(19) United States
(12) Patent Application Publication
(10) Pub. No.: US 2008/0206952 A1
(43) Pub. Date: Aug. 28, 2008

(54) Silicon Substrate Processing Method

(76) Inventors: Seiichi Nagata, Shizuoka (JP); Junichi Murata, Shizuoka (JP)

Correspondence Address: DRINKER BIDDLE & REATH (DC), 1500 K STREET, N.W., SUITE 1100, WASHINGTON, DC, 20005-1209, US

(21) Appl. No.: 11/664,158

(22) PCT Filed: Sep. 29, 2005
(86) PCT No.: PCT/JP2005/018000

§ 371 Date: Jan. 2, 2008

(30) Foreign Application Priority Data
Sep. 30, 2004 (JP) 2004-287679

(51) Int. Cl. H01L 21/76

(52) U.S. Cl. 438/409; 257/E21.54

(57) ABSTRACT

In a thin film forming step S1, a thin film, having carbon as a main component, is formed on at least one principal surface of a silicon substrate. In a thin film partial removal step S2, of the thin film, a thin film portion at a partial region on the one principal surface is removed. In a porous region forming step S3, the portion of the carbon thin film remaining after the removal of the thin film portion at the partial region in the previous thin film partial removal step S2 is used as a mask and the silicon substrate is anodized in an electrolytic solution containing hydrofluoric acid to selectively form a porous silicon region in a surrounding region including the partial region from which the thin film has been removed. In a remaining thin film portion removal step S4, the remaining portion of the thin film on the one principal surface of the silicon substrate is removed under the oxidizing atmosphere, and at the same time, at least a portion of the porous silicon region is oxidized. A silicon substrate processing method is thereby provided with which the respective processes for forming and removing a thin film, used as a mask in the selective forming of porous silicon, are excellent in terms of practical use.

### TECHNICAL FIELD

This invention relates to a method for processing a silicon substrate and particularly concerns a method for forming a porous silicon region in a portion of at least one principal surface side of a silicon substrate.

### BACKGROUND ART

Porous silicon is a substance of extremely large specific surface area (several hundred m²/cm³) in which nanosize pores and fine silicon columns of substantially the same size as the pores coexist. Porous silicon is characterized by its porosity (proportion of pore volume per unit volume), pore diameter, and distribution widths of the porosity and the pore diameter.

Methods for processing a silicon substrate to form a porous silicon region in a portion of at least one principal surface side of the silicon substrate are, for example, described in a Patent Document 1 and a Non-Patent Document 1. With the silicon substrate processing methods described in these documents, a thin film, constituted of silicon nitride (SiNx) or silicon carbide (SiC), is formed on one principal surface of a silicon substrate, and of the thin film, a thin film portion at a partial region of the one principal surface is removed, and by performing anodization in an electrolytic solution containing hydrofluoric acid, a porous silicon region is formed selectively in a surrounding region including the thin-film-removed region. The remaining portion of the thin film is thereafter removed. Or, the porous silicon region is made to contain an additive, the porous silicon region is oxidized, or the porous silicon region is densified.

Porous silicon, which has been selectively formed by rigorous control of porosity and pore diameter, has excellent properties, and optical waveguides, optical integration circuit devices, etc., that make use of these excellent properties have been developed. For example, by converting selectively anodized porous silicon to silica by oxidation and densification, the silica can be used as an optical waveguide. In this case, the volume of the densified silica is preferably substantially equal to the volume of the porous silicon before oxidation.

The density and volume of silica after densification differ according to the processing method. The porosity with which the volume change will be zero varies somewhat according to the density of the silica that is formed. In the Patent Document 1 and the Non-Patent Document 1, it is indicated that by controlling the porosity of the porous silicon to be close to 55%, the volume of the silica after densification can be made substantially equal to the volume of the porous silicon.

In the Patent Document 1 and the Non-Patent Document 1, the hydrofluoric acid concentration of the electrolytic solution, the current density at an interface of porous silicon and silicon, and the doping characteristics of the silicon substrate are cited as parameters for preparing porous silicon by anodization. It is furthermore indicated that by adjusting the combination of the hydrofluoric acid concentration and the current density, porous silicon having the desired combination of porosity and pore diameter can be prepared, that is, porous silicon having a porosity close to 55% and a desired, arbitrary pore diameter can be prepared.

By thus preparing porous silicon, which is precisely controlled in porosity and pore diameter, and using this porous silicon without degrading the excellent characteristics, various new useful devices can be prepared.

The thin film that is used as a mask in selectively forming porous silicon is required to satisfy the three conditions of: withstanding immersion in a high-concentration hydrofluoric acid solution for a long period of time (no less than approximately 10 minutes) (this condition shall be referred to hereinafter as “Condition 1”); enabling fine photopatterning (this condition shall be referred to hereinafter as “Condition 2”); and enabling removal of the remaining thin film layer without applying a serious ill effect on the porous silicon after formation of the porous silicon (this condition shall be referred to hereinafter as “Condition 3”).

Although the silicon nitride film (SiNx), silicon carbide film (SiC), etc., that are used in silicon substrate processing methods described in the Patent Document 1 and the Non-Patent Document 1 satisfy the Conditions 1 and 2 described above, these films do not satisfy the Condition 3. That is, although porous silicon can be formed using these mask layers, after the selective formation of the porous silicon, the mask layers that have completed their roles cannot be removed without applying a serious ill effect on the prepared porous silicon. This point shall now be described.

FIG. 10 shows diagram of a sectional structure of porous silicon for describing the issue of the conventional silicon substrate processing method. As shown in FIG. 10(a), porous silicon basically contains nanosize fine silicon columns 100, which are formed of crystalline silicon, and pores 110, of substantially the same size as the columns, in a mixed manner. That is, pores 110, which are voids, and fine silicon columns 100, in which silicon atoms exist, are present in the porous silicon region, and the porosity is defined as the volume percentage of the pores 110 in a unit volume of porous silicon. Totaling of the surface areas of all of the fine silicon columns 100, in porous silicon of such fine structure, results in an enormous specific surface area in the order of several hundred m²/cm³.

To remove a silicon nitride film (SiNx) or a silicon carbide film (SiC), a fluorine-based plasma etching means is employed. When such a fluorine-based etchant is used, not just the thin film, but the fine columns 100 of crystalline silicon are also etched. That is, when the fluorine-based etchant enters into the porous silicon through the pores 110 and etches silicon atoms of even a small number of atomic layers at surfaces of the fine silicon columns 100, the fine silicon columns 100 are thinned by an amount corresponding to loss portions 130 thereof and pores 112 increase in diameter correspondingly as shown in FIG. 10(b). An extremely large number of silicon atoms are thus lost across all surfaces inside the porous silicon region. This is because the porous silicon is a porous substance of extremely large specific surface area as mentioned above, and even when a small number of atomic layers are etched from the large surface area by entry of the etchant into the pores, a serious effect is applied to the porosity and the pore diameter.

Here, a concept called “etching selectivity” shall be described. The etching selectivity is defined as the ratio (Ro/Rs), where Ro is an etching rate of a material to be etched (thin film of SiNx or SiC), and Rs is the rate, at which a material (porous silicon) to be left without becoming etched even in an etching atmosphere is etched unavoidably in the etching atmosphere. Although the etching selectivity (Ro/Rs) in the above-described case is substantially 1, because the porous silicon is porous, the porous silicon is effectively etched faster. Thus, even if the porosity and the pore diameter are controlled precisely during porous silicon preparation, the critical ill effect of these becoming disrupted cannot be avoided in the mask layer removal step.

Meanwhile, with a silicon substrate processing method described in a Non-Patent Document 2, by irradiating an electron beam onto a predetermined pattern on a principal surface of a silicon substrate in a vacuum, “contaminated” by organic molecules, a carbon film is deposited on the electron beam irradiated portion and a porous silicon region is selectively formed by performing anodization using the carbon film deposited on the predetermined pattern as a mask.

Patent Document 1: Japanese Published Unexamined Patent Application No. H11-242125
Non-Patent Document 1: S. Nagata, et al., “Silica waveguides fabricated by oxidization of selectively anodized porous silicon,” Appl. Phys. Lett., Vol. 82, No. 16, pp. 2559-2561 (2003)
Non-Patent Document 2: T. Djenizian, et al., “Electron beam induced carbon deposition used as a negative resist for selective porous silicon formation,” Surface Science, 524 (2003) pp. 40-48

### DISCLOSURE OF THE INVENTION

### Problems to be Solved by the Invention

However, with the method described in the Non-Patent Document 2, because the carbon film is deposited by irradiating an electron beam onto the principal surface of the silicon substrate, the electron beam must be irradiated at a high irradiation density to deposit a carbon film having a thickness required of a mask and a long time that is not practical in industrial terms is required to form the mask of the predetermined pattern on the principal surface of the silicon substrate. Also, although this carbon film functions as a resist, with this carbon film, it cannot be the fact that adequate durability is secured in regard to anodizing conditions, the reproducibility and reliability of which are rigorously required industrially. The method described in the Non-Patent Document 2 thus lacks in practicality. Also, the Non-Patent Document 2 does not mention anything in regard to the removal of the remaining mask portion after formation of the porous silicon.

This invention has been made to resolve the above issues, and an object thereof is to provide a silicon substrate processing method, with which respective processes for forming and removing a thin film, used as a mask in selective forming of porous silicon, are excellent in terms of practical use.

### SUMMARY OF THE INVENTION

To achieve the above object, the above-described Conditions 1 and 2 must be satisfied and the Condition 3 must furthermore be satisfied. That is, a thin film, formed of a material that can be removed by an etchant, which does not remove silicon atoms from a surface of porous silicon of extremely large specific surface area, must be used as a selective forming mask. Put in another way, a main theme of this invention is to provide methods for forming and removing a mask that realizes conditions of an etching selectivity (Ro/Rs) much greater than 1.

With the present invention, a thin film, formed of a carbon-based material, is used as a mask. By oxidation, the carbon-based substance vaporizes as carbon dioxide or other high vapor pressure substance. In an atmosphere of activated oxygen (oxygen under ultraviolet ray irradiation, ozone, or oxygen plasma, etc.), the carbon-based substance is oxidized even at room temperature. The carbon-based substance is also oxidized under an oxygen atmosphere at a high temperature (no less than approximately 500° C.).

Meanwhile, when porous silicon is exposed to an activated oxygen atmosphere near room temperature, the activated oxygen permeates uniformly into the interior of the porous silicon through the pores 110 and oxidize the outermost surfaces of the fine silicon columns 100, thereby forming thin SiO₂ layers 120 as shown in FIG. 11B. The rate of this reaction is dependent on the supply of the activated oxygen, and when the silicon atoms on the surface of the fine silicon columns 100 become oxidized, further oxidation of the silicon atoms of fine column interiors 101 is prevented. The oxidized layers 120 are dense, stable, low in vapor pressure even at high temperatures, and prevent loss of the silicon atoms.

To increase the thickness of the oxidized surface layers 120, the substrate temperature is raised in an oxidizing atmosphere to enter a diffusion-limited reaction process in which the activated oxygen permeates into the interiors of the oxidized layers 120 by diffusion. The thickness of the thermally oxidized layers 120 on the surfaces of the fine silicon columns 100 obeys a relationship between oxidized layer thickness and temperature of thermal oxidation of normal crystalline silicon. Thus, when the fine silicon columns 100 are thin, total oxidation into the interiors of the fine columns 100 occurs even at a low temperature, and as the fine columns 100 increase in diameter, the temperature required to totally oxidize the fine columns 100 increases.

Whereas the oxide of carbon is a gas, such as CO, CO₂, etc., the oxide, SiO₂, of silicon forms a dense, stable, solid thin film that is extremely low in vapor pressure even at high temperatures. This is the reason why the above-described etching selectivity can be made extremely large.

The mask thin film is thus formed of a carbon-based material, this thin film is patterned by oxygen plasma, etc., and after selectively forming porous silicon, the remaining mask layer is removed by plasma oxidation or thermal oxidation. The mask layer can thereby be removed without vaporizing the silicon elements forming the porous silicon region.

That is, a silicon substrate processing method according to this invention includes: (1) a thin film forming step of forming a thin film, having carbon as a main component, on at least one principal surface of a silicon substrate; (2) a thin film partial removal step of removing, from among the thin film formed in the thin film forming step, a thin film portion at a partial region of the one principal surface; (3) a porous region forming step of selectively forming a porous silicon region at a surrounding region including the partial region, by subjecting the silicon substrate, which has been subject to the thin film partial removal step, to anodization in an electrolytic solution containing hydrofluoric acid; and (4) a remaining thin film portion removal step of removing the remaining portion of the thin film on the one principal surface of the silicon substrate, which has been subject to the porous region forming step, in an oxidizing atmosphere and, at the same time, oxidizing at least a portion of the porous silicon region.

With the silicon substrate processing method according to this invention, the thin film, having carbon as the main component, is formed on at least one principal surface of the silicon substrate in the thin film forming step, and of the thin film, the thin film portion on the partial region of the one principal surface is removed in the subsequent thin film partial removal step, and the remaining portion of the thin film is used as a mask in the porous region forming step that follows. Furthermore, in the subsequent porous region forming step, by the silicon substrate being anodized in the electrolytic solution that contains hydrofluoric acid, the porous silicon region is formed selectively at the surrounding region including the partial region from which the thin film has been removed. Then, in the remaining thin film portion removal step that follows, the remaining portion of the thin film on the one surface of the silicon substrate is removed under the oxidizing atmosphere and, at the same time, at least a portion of the porous silicon region is oxidized.

The region that is oxidized at the same time as the removal of the remaining portion of the thin film in the oxidizing atmosphere in the remaining thin film portion removal step may be a portion of the porous silicon region (outermost surface layers of fine silicon columns) or may be the entirety of the porous silicon region. Also preferably, in the remaining thin film portion removal step, at the same time as removing the remaining portion of the thin film in the oxidizing atmosphere the entirety of the porous silicon region is oxidized and furthermore densified.

Preferably, the thin film formed in the thin film forming step is a hard carbon film. Also preferably, the oxidizing atmosphere in the remaining thin film portion removal step is an oxygen-containing atmosphere of no less than 500° C., a plasma atmosphere, having oxygen as a main component, an ozone atmosphere, or a strongly oxidizing liquid atmosphere.

Also preferably, with the silicon substrate processing method according to this invention, in the thin film forming step, a hydrogen termination treatment is applied to a surface of at least one principal surface of the silicon substrate and the thin film having carbon as the main component is formed thereafter.

Also preferably, the silicon substrate processing method according to the invention, further includes an adding step of adding an additive to the porous silicon region formed by the porous matter forming step, and in which in the remaining thin film portion removal step, the remaining portion of the thin film on the one principal surface of the silicon substrate, which has been subject to the adding step, is removed in an oxidizing atmosphere and at the same time, at least a portion of the porous silicon region is oxidized.

Also, in a case where an additive is to be added to the porous silicon region, an adding step of adding the additive to the porous silicon region of the silicon substrate, which has been subject to the remaining thin film portion removal step, is preferably provided.

Also preferably, the silicon substrate processing method according to this invention, further includes a second thin film forming step of forming a second thin film, having carbon as a main component, on the one principal surface of the silicon substrate, which has been subject to the porous region forming step, a second thin film partial removal step of removing a portion of a portion of the second thin film positioned above the porous silicon region, an adding step of adding an additive to the porous silicon region via the portion of the second thin film that has been removed by the second thin film partial removal step, and a second remaining thin film portion removal step of removing the remaining portion of the second thin film on the one principal surface, which has been subject to the adding step, in an oxidizing atmosphere and at the same time oxidizing at least a portion of the porous silicon region.

Also preferably, the silicon substrate processing method according to this invention, further includes a second thin film forming step of forming a second thin film, having carbon as a main component, on the one principal surface of the silicon substrate, which has been subject to the porous region forming step, a second thin film partial removal step of removing a portion of a portion of the second thin film positioned above the porous silicon region, and an adding step of adding an additive to the porous silicon region via the portion of the second thin film that has been removed by the second thin film partial removal step, and wherein in the remaining thin film portion removal step, the remaining portion of thin films, having carbon as a main component, on the one principal surface, which has been subject to the adding step, is removed in an oxidizing atmosphere and at the same time, at least a portion of the porous silicon region is oxidized.

### EFFECTS OF THE INVENTION

Conventionally, a silicon compound, such as silicon nitride, silicon carbide, etc., is used as the thin film to be employed as a mask in the selective formation of porous silicon. In removing such a silicon compound thin film, the silicon component is removed as a fluoride by a fluorine-based plasma, etc. Such conventional methods accompany the extremely detrimental side effects of loss of silicon atoms as fluoride from even the surface of porous silicon of extremely large specific surface area.

With the present invention, a carbon thin film is used as the thin film to be employed as the mask. Carbon is oxidized by an oxidizing atmosphere, and oxides of carbon disappear as gas even at room temperature. Meanwhile, when silicon is oxidized, a dense, stable silicon oxide thin film of extremely low vapor pressure is formed. Thus, as a first effect, even if the outermost surface atoms of the porous silicon of large specific surface area are oxidized by exposure to the oxidizing atmosphere for removal of the carbon thin film after its use as a mask layer, the serious ill effect of loss of silicon atoms from the porous silicon region does not occur. By this advantage, the following effects are also exhibited.

As a second effect, selective doping of an additive is enabled after removal of the carbon thin film in the remaining thin film portion removal step. As a third effect, use of a carbon thin film as a mask layer again for selective doping of the additive is enabled. As a fourth effect, by oxidizing the entirety of the porous silicon region by, for example, subjecting the silicon substrate to an oxidizing, high-temperature heat treatment, the carbon thin film, employed as the mask layer, can be made to disappear automatically as well. A special step for removing the carbon thin film is thus made unnecessary. Also, in such a case where the carbon thin film is made to disappear automatically by the oxidizing, high-temperature heat treatment, periodic uneven structures, which are detrimental, are not formed as in a second comparative example to be described below. This invention thus provides enormous effects in terms of industry.

### BRIEF DESCRIPTION OF THE DRAWINGS

FIG. 1 is a flowchart for describing a silicon substrate processing method according to an embodiment.

FIG. 2 shows sectional view for describing step of a silicon substrate processing method according to a first embodiment.

FIG. 3 shows sectional view for describing step of a silicon substrate processing method according to a second embodiment.

FIG. 4 shows sectional view for describing step of a silicon substrate processing method according to a third embodiment.

FIG. 5 shows sectional view for describing step of a silicon substrate processing method according to a fourth embodiment.

FIG. 6 shows sectional view for describing step of a silicon substrate processing method according to a fifth embodiment.

FIG. 7 shows sectional view for describing step of a silicon substrate processing method according to a fifth embodiment.

FIG. 8 shows sectional view for describing step of a silicon substrate processing method according to a first comparative example.

FIG. 9 shows sectional view for describing step of a silicon substrate processing method according to a second comparative example.

FIG. 10 shows schematic view of a sectional structure of porous silicon for describing issues of a conventional silicon substrate processing method.

FIG. 11 shows schematic view of a sectional structure of porous silicon for describing a silicon substrate processing method according to this invention.

FIG. 12 shows sectional view for describing step of yet another embodiment of a silicon substrate processing method according to this invention.

FIG. 13 shows sectional view for describing step of a silicon substrate processing method according to a sixth embodiment of this invention.

FIG. 14 shows sectional view for describing step of a silicon substrate processing method according to a sixth embodiment of this invention.

FIG. 15 show sectional view for describing step of yet another embodiment of a silicon substrate processing method according to this invention.

### DESCRIPTION OF THE SYMBOLS

10 . . . silicon substrate, 11 . . . first mask layer constituted of a carbon thin film, 12 . . . opening, 13 . . . second mask layer constituted of a second carbon thin film, 14 . . . third mask layer constituted of a third carbon thin film, 17 . . . first mask layer constituted of a silicon nitride film, 20-22 . . . porous silicon region, 30-32 . . . porous silicon region doped with an additive, 40-43 . . . silica region, 50-52 . . . silica region, 70-71 . . . periodic unevenness, 80 . . . upper clad

### BEST MODES FOR CARRYING OUT THE INVENTION

Best modes for carrying out this invention shall now be described in detail with reference to the attached drawings. In the description of the drawings, elements that are the same shall be provided with the same symbols and redundant description shall be omitted.

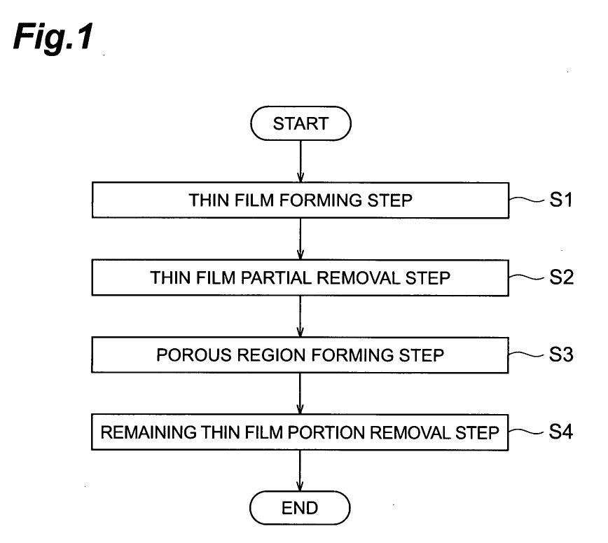

FIG. 1 is a flowchart for describing steps of a silicon substrate processing method according to an embodiment. The flowchart in this figure illustrates a most basic flow of the silicon substrate processing method according to the embodiment.

First in a thin film forming step S1, a thin film, having carbon as a main component, is formed on at least one principal surface of a silicon substrate. The thin film that is formed here is preferably a hard carbon film, and is preferably, for example, diamond-like carbon or carbon nitride. Also, to form the carbon film on the principal surface of the silicon substrate, for example, a carbon compound, such as benzene, etc., is thermally dissociated to generate carbon ions and the carbon ions are deposited onto the silicon substrate by an electric field.

In a thin film partial removal step S2 that follows, of the thin film, a thin film portion at a partial region of the one principal surface is removed. More specifically, a resist is coated onto the carbon thin film, this resist is exposed using a photomask to prepare a resist pattern, an opening of a predetermined pattern is formed in the carbon thin film by reactive ion etching (RIE), mainly using oxygen, and thereafter, the remaining resist is removed.

In a subsequent porous region forming step S3, the portion of the carbon thin film, remaining after removal of the thin film portion at the partial region in the previous thin film partial removal step S2, is used as a mask, and the silicon substrate is anodized in an electrolytic solution, containing hydrofluoric acid, to selectively form a porous silicon region at a surrounding region including the partial region from which the thin film has been removed. In order to selectively form porous silicon, which is controlled to be uniform in porosity and pore diameter, in this process, it is important to keep fixed the hydrofluoric acid concentration and the current density used in the anodization.

Then, in a subsequent remaining thin film portion removal step S4, the remaining portion of the thin film on the one principal surface of the silicon substrate is removed under an oxidizing atmosphere and, at the same time, at least a portion of the porous silicon region is oxidized. In this step, the region, from which the remaining portion of the thin film is to be removed under the oxidizing atmosphere and which is to be oxidized at the same time, may be a portion of the porous silicon region (outermost layers of fine silicon columns) or may be the entirety of the porous silicon region. Also preferably, in this step, at the same time as removing the remaining portion of the thin film in the oxidizing atmosphere, the entirety of the porous silicon region is oxidized and furthermore densified. Preferably, the oxidizing atmosphere in the remaining thin film portion removal step is an oxygen-containing atmosphere of no less than 500° C., a plasma atmosphere, having oxygen as a main component, an ozone atmosphere, or an atmosphere of a strongly oxidizing liquid (for example, nitric acid, hot sulfuric acid, a mixture of hydrogen peroxide solution and sulfuric acid, etc.).

Various modifications of the silicon substrate processing method according to this embodiment are possible on the basis of the flow shown in FIG. 1. For example, an additive (for example, an element such as Ge, Ti, Zr, Hf, Ta, Nb, etc., that is mixed with silica to increase the refractive index of silica, or an optically active rare earth element as represented by Pr, Nd, Er, Tm, etc., or transition metal element, such as Cr, etc.) may be added into the porous silicon region before densification. In the porous region forming step S3, a plurality of layers of porous silicon regions that mutually differ in porosity may be formed on the principal surface of the silicon substrate, and one or a plurality of types of the additives belonging to the above-mentioned groups may be selectively added into any of these plurality of porous silicon region layers. Also, in the remaining thin film portion removal step S4, a portion of the porous silicon region (outermost layers of fine silicon columns) may be oxidized at the same time as removing the remaining portion of the thin film under the oxidizing atmosphere, and by thereafter applying the thin forming step S1 and the thin film partial removal step S2 again, an additive may be selectively added into any of the plurality of porous silicon regions already formed on the principal surface of the silicon substrate.

The silicon substrate processing method according to this invention shall now be described by way of first to fifth embodiments that are more specific and a first comparative example and a second comparative example for comparison with the embodiments. The first comparative example and a third comparative example are to be compared with the first embodiment, and the second comparative example is to be compared with the fourth embodiment.

### First Embodiment

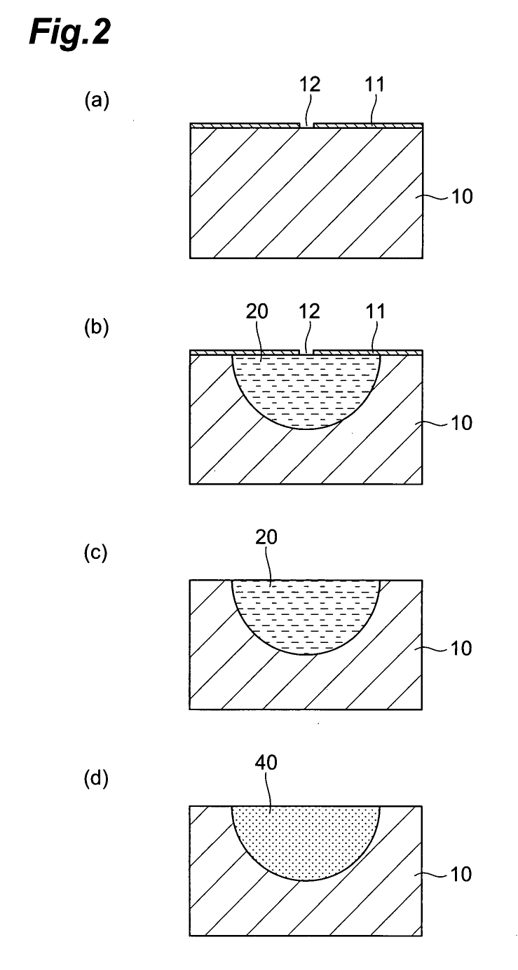

The first embodiment of the silicon substrate processing method according to this invention shall now be described. FIG. 2 shows sectional view for describing step of the silicon substrate processing method according to the first embodiment. FIG. 2(a) shows a silicon substrate section after the thin film forming step S1 and the thin film partial removal step S2. FIG. 2(b) shows the silicon substrate section after the porous region forming step S3. FIG. 2(c) shows the silicon substrate section after oxidation in the remaining thin film portion removal step S4. FIG. 2(d) shows the silicon substrate section after densification in the remaining thin film portion removal step S4.

In the thin film forming step S1 in the first embodiment, a highly-doped, p-type (100) silicon substrate 10 of 3-inch diameter is first subject to a surface treatment. More specifically, organic contaminants and oxides of silicon that are attached to the surface of the silicon substrate 100 are removed, and a hydrogen termination process of terminating the surface of the silicon substrate 100 with hydrogen is performed. The silicon substrate 10 is then mounted on a substrate holder inside a vacuum device for film forming. Inside the vacuum container, benzene vapor is made to flow through an ion source, having a cathode with a heating filament and an anode, the benzene is thermally dissociated by the filament to generate partially ionized carbon, and the carbon is drawn out toward the anode to irradiate the substrate and form a carbon thin film 11 on a principal surface of the silicon substrate 10. A carbon thin film layer of approximately 100 nm thickness can thereby be formed on the silicon substrate 10.

In the thin film partial removal step S2 in the first embodiment, a resist is coated to a thickness of approximately 1.5 μm onto the silicon substrate 10, on which the carbon thin film 11 has been formed, a resist pattern is formed by exposure using a photomask, a desired opening 12 is formed in the carbon thin film 11 by reactive ion etching (RIE), mainly using oxygen, and thereafter the resist is removed. Here, although the resist is greater in the rate of etching by oxygen plasma than the carbon film, because the film thickness ratio of the carbon film and the resist is extremely small, the carbon film can be patterned without any problem (FIG. 2(a)).

In the porous region forming step S3 in the first embodiment, in order to selectively form porous silicon that is controlled to be uniform in both porosity and pore diameter, the hydrofluoric acid concentration used in anodization and the current density at the interface of porous silicon and silicon are kept fixed. As described in the Patent Document 1 and the Non-Patent Document 1, a pulse current chemical conversion method, in which a chemical conversion current is increased proportionally to the area of the interface between porous silicon and silicon as the porous silicon region grows, is employed. The silicon substrate 10, with which patterning was applied to the carbon film in the thin film partial removal step S2, is used as an anode, an opposing platinum electrode is used as a cathode, and while maintaining a hydrofluoric acid solution of predetermined concentration between the electrodes, the silicon substrate 10 is anodized (chemically converted) to form a porous silicon region 20 (FIG. 2(b)). The hydrofluoric acid concentration and the interface current density, which are chemical conversion parameters, are adjusted to make the porosity of the porous silicon region 20 approximately 56%.

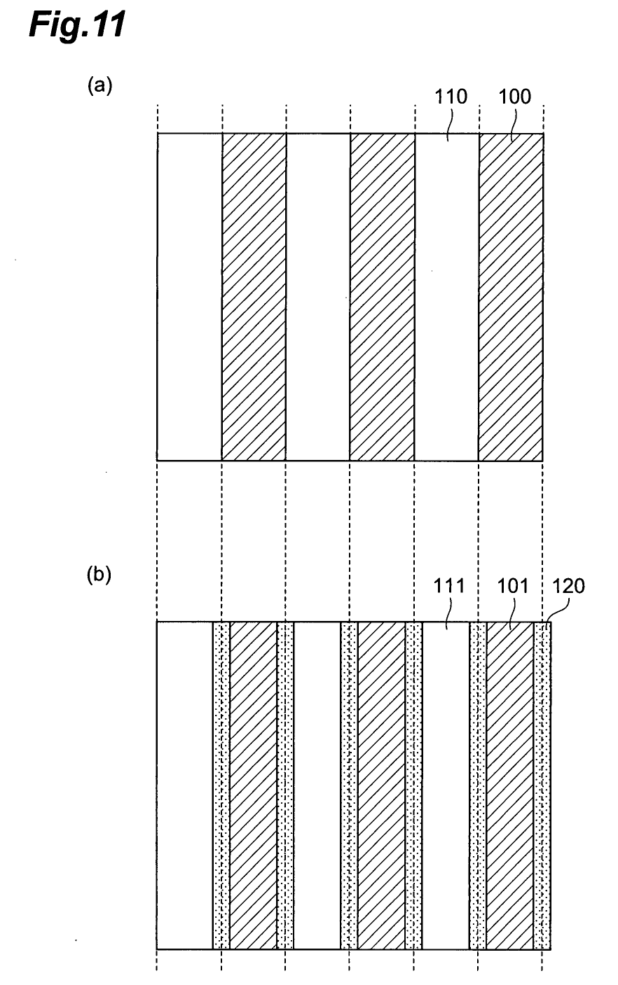

In the remaining thin film portion removal step S4 in the first embodiment, the silicon substrate 10, in which the porous silicon region 20 was selectively formed by means of the carbon film 11 and the opening 12, is held inside a normal RIE device or a resist ashing device that uses oxygen plasma. Then, by means of the oxygen plasma, the carbon film 11 is oxidized and removed and, at the same time, the surfaces of the fine silicon columns 100 inside the porous silicon region 20 are oxidized (FIG. 2(c), FIG. 11(b)). Also, after oxidation, heating is furthermore performed to densify and convert the porous silicon region 20 to a silica region 40 (FIG. 2(d)).

After actually forming a porous silicon region 20 on a silicon substrate 10 by the silicon substrate processing method according to the first embodiment described above, only a slight change of mass in the order of several tenths of a milligram, which is within the range of error, was seen in the total mass of the silicon substrate before and after the subsequent remaining thin film portion removal step S4. This is considered to be because the loss of mass accompanying the oxidation loss of the carbon film 11 was substantially cancelled out by the increase in mass due to the formation of the surface oxidized layers 120 by surface oxidation of the fine silicon columns 100 inside the porous silicon region 20 as shown in the conceptual diagram of FIG. 11(b).

### Second Embodiment

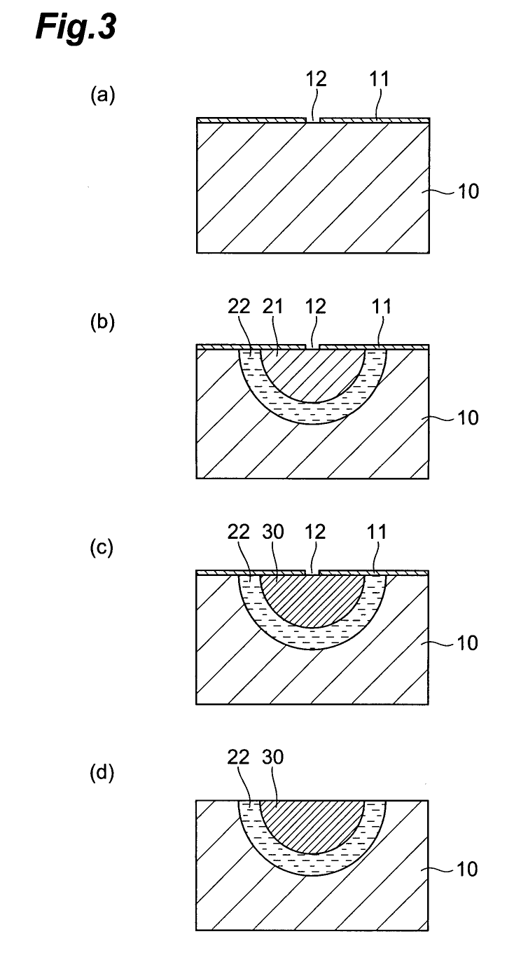

The second embodiment of the silicon substrate processing method according to this invention shall now be described. FIG. 3 shows sectional view for describing step of the silicon substrate processing method according to the second embodiment. FIG. 3(a) shows a silicon substrate section after the thin film forming step S1 and the thin film partial removal step S2. FIG. 3(b) shows the silicon substrate section after the porous region forming step S3. FIG. 3(c) shows the silicon substrate section, with which an additive is doped into the porous silicon region after the porous region forming step S3. FIG. 3(d) shows the silicon substrate section after the remaining thin film portion removal step S4.

The thin film forming step S1 and the thin film partial removal step S2 in the second embodiment are respectively the same as the same steps in the first embodiment (FIG. 3(a)).

The porous region forming step S3 in the second embodiment is substantially the same as the same step in the first embodiment. However, in the second embodiment, a first porous silicon region 21 and a second porous silicon region 22 are prepared in a continuous manner as described in the Patent Document 1 and the Non-Patent Document 1 (FIG. 3(b)). Both the regions 21 and 22 have a porosity of approximately 56%. The pore diameter of the region 21 at the inner side is larger than the pore diameter of the region 22 at the outer side. The combination of the hydrofluoric acid concentration and the interface current density used for chemical conversion is adjusted to realize these characteristics.

In the second embodiment, after the porous region forming step S3, an additive is doped into the porous silicon region 20 as shown in FIG. 3(c) (adding step). More specifically, after washing and drying the silicon substrate 10, in which the porous silicon regions 21 and 22 have been formed as described above, the silicon substrate 10 is immersed for a fixed time in a solution of a titanium organometallic compound in a nitrogen atmosphere at room temperature. By this operation, the titanium organometallic compound molecules are selectively doped into the first porous silicon region 21. The organometallic compound, the solvent thereof, etc., that have become attached to the surface of the substrate 10 are then removed and the solvent and organic components inside the porous silicon regions 21 and 22 are removed. The porous silicon region 21 can thereby be converted into a porous region 30 that is selectively doped with an oxide of titanium.

In the remaining thin film portion removal step S4 in the second embodiment, the silicon substrate, with which the above-described processes have been completed, is subject to the oxygen plasma treatment in the same manner as in the first embodiment to remove the mask layer 11 of the carbon film and oxidize the surfaces of the fine silicon columns 100 inside the porous silicon regions 30 and 22 (FIG. 3(d)). Also, after oxidation, heating may furthermore be performed to density and convert the porous silicon regions 30 and 20 into silica regions, respectively.

By the silicon substrate processing method according to the second embodiment described above, porous silicon regions 21 and 22 were actually formed in a silicon substrate 10 and then the porous silicon region 21 was selectively doped with a titanium oxide and thereby converted into a porous region 30. The change of the total mass of the silicon substrate before and after the remaining thin film portion removal step S4 was extremely slight in this case as well.

### Third Embodiment

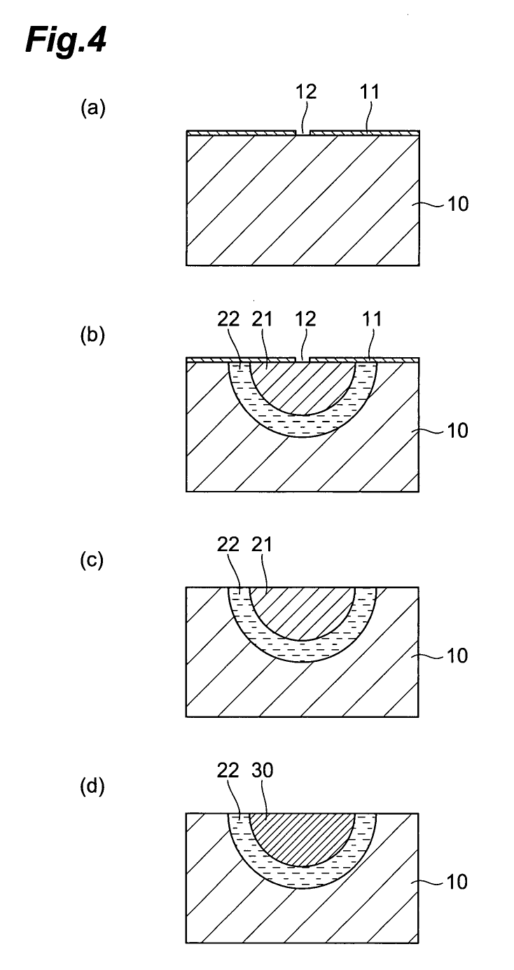

The third embodiment of the silicon substrate processing method according to this invention shall now be described. FIG. 4 shows sectional view for describing step of the silicon substrate processing method according to the third embodiment. FIG. 4(a) shows a silicon substrate section after the thin film forming step S1 and the thin film partial removal step S2. FIG. 4(b) shows the silicon substrate section after the porous region forming step S3. FIG. 4(c) shows the silicon substrate section after oxidation in the remaining thin film portion removal step S4. FIG. 4(d) shows the silicon substrate section, with which an additive is doped into the porous silicon region after the remaining thin film portion removal step S4.

The thin film forming step S1 and the thin film partial removal step S2 in the third embodiment are respectively the same as the same steps in the first embodiment and the second embodiment (FIG. 4(a)). The porous region forming step S3 in the third embodiment is the same as the same step in the second embodiment (FIG. 4(b)). The remaining thin film portion removal step S4 in the third embodiment is the same as the same step in the first embodiment (FIG. 4(c)).

In the third embodiment, after the remaining thin film portion removal step S4 (FIG. 4(c)), an additive is doped into the porous silicon region 21 as shown in FIG. 4(d) (adding step). More specifically, after washing and drying the silicon substrate 10 (FIG. 4(c)), from which the remaining thin film portion has been removed, the silicon substrate 10 is immersed for a fixed time in a solution of a titanium organometallic compound in a nitrogen atmosphere at room temperature. By this operation, the titanium organometallic compound molecules are selectively doped into the first porous silicon region 21. The organometallic compound, the solvent thereof, etc., that have become attached to the surface of the substrate 10 are then removed and the solvent and organic components inside the porous silicon regions 21 and 22 are removed. The porous silicon region 21 can thereby be converted into a porous region 30 that is selectively doped with an oxide of titanium.

By the silicon substrate processing method according to the third embodiment described above, porous silicon regions 21 and 22 were actually formed in a silicon substrate 10 and then the region 21 was selectively doped with titanium and thereby converted into a porous region 30. The change of the total mass of the silicon substrate before and after the remaining thin film portion removal step S4 was extremely slight in this case as well. Also, in comparison to the second embodiment, the amount of impurity supplied to the region 21 increased with the third embodiment. Also, in the region 22, doping of titanium was seen only in a surface layer in contact with the principal surface of the silicon substrate 10.

### Fourth Embodiment

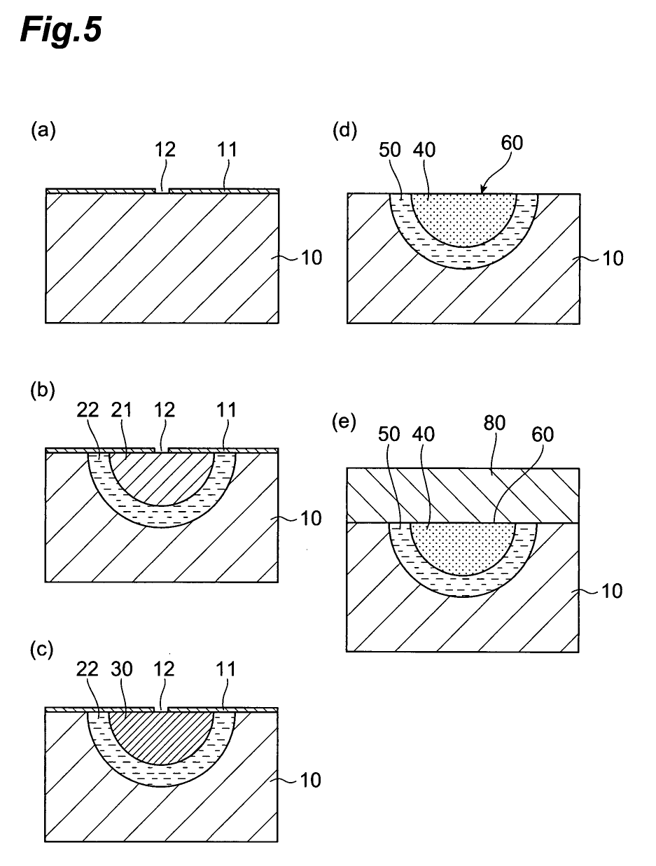

The fourth embodiment of the silicon substrate processing method according to this invention shall now be described. FIG. 5 shows sectional view for describing step of the silicon substrate processing method according to the fourth embodiment. FIG. 5(a) shows a silicon substrate section after the thin film forming step S1 and the thin film partial removal step S2. FIG. 5(b) shows the silicon substrate section after the porous region forming step S3. FIG. 5(c) shows the silicon substrate section, with which an additive is doped into the porous silicon region after the porous region forming step S3. FIG. 5(d) shows the silicon substrate section after oxidation and densification in the remaining thin film portion removal step S4. FIG. 5(e) shows the silicon substrate section, with which an upper clad is formed after the remaining thin film portion removal step S4.

The thin film forming step S1 and the thin film partial removal step S2 in the fourth embodiment are respectively the same as the same steps in the second embodiment (FIG. 5(a)). The porous region forming step S3 in the fourth embodiment is the same as the same step in the second embodiment (FIG. 5(b)). The impurity adding step in the fourth embodiment is the same as the same step in the second embodiment (FIG. 5(c)).

In the fourth embodiment, the porous silicon region is oxidized and furthermore densified in the remaining thin film portion removal step S4 (FIG. 5(d)).

More specifically, the substrate 10, which has been subject to the above-described doping treatment, is subject to an oxidation treatment at a temperature of 850° C. in an electric oven through which dry oxygen gas is made to flow. By this treatment, the fine silicon columns in the porous silicon regions 30 and 22 are completely oxidized up to the central portions thereof and are converted into porous silica. At the same time, the carbon film 11 is oxidized and disappears completely.

The substrate 10 is furthermore treated in a wet oxygen flow of 1200° C. to convert the porous silica into dense silica regions 40 and 50. The region 40 is doped with titanium and exhibits a property as a core that is increased in refractive index. The region 50 is non-doped silica and exhibits a property as a clad of low refractive index. By the heat treatment at the temperature of 1200° C., the silica is put in a fused state that exhibits viscous fluidity and is thereby densified. In this process, because surfaces 60 of the regions 40 and 50 at the side of the principal surface of the substrate are in states of free surfaces that do not contact any solid substance, the history of fusion and flow as free surfaces is preserved and the surfaces 60 are thus made extremely smooth.

In the fourth embodiment, an upper clad 80 is formed on the principal surface of the silicon substrate 10 after the remaining thin film portion removal step S4 (FIG. 5(e)). This upper clad 80 is formed, for example, of silica. By the above-described processes, if the regions 40 and 50 are long in one direction (the direction perpendicular to the paper surface), a optical waveguide, having the region 50 and the upper clad 80 as clads and the region 40 as a core, is prepared.

### Fifth Embodiment

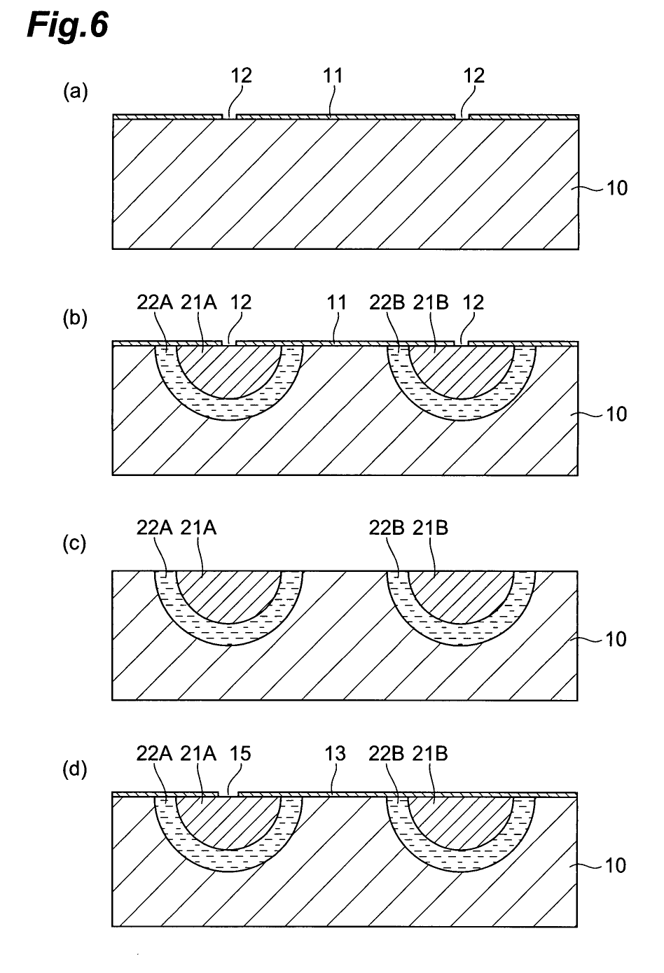

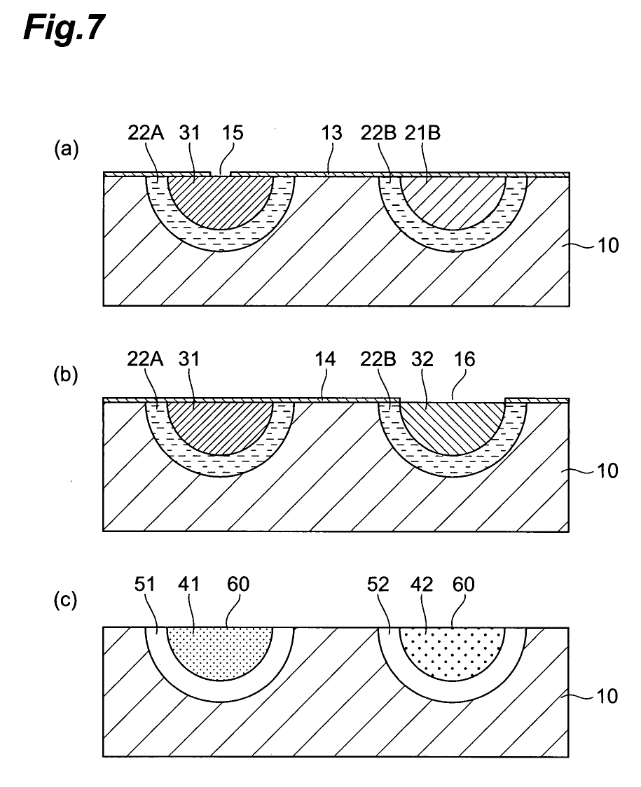

The fifth embodiment of the silicon substrate processing method according to this invention shall now be described. FIG. 6 and FIG. 7 show sectional views for describing steps of the silicon substrate processing method according to the fifth embodiment. FIG. 6(a) shows a silicon substrate section after the thin film forming step S1 and the thin film partial removal step S2. FIG. 6(b) shows the silicon substrate section after the porous region forming step S3. FIG. 6(c) shows the silicon substrate section after the remaining thin film portion removal step S4. FIG. 6(d) shows the silicon substrate section after a second mask is formed following the step of FIG. 6(c). FIG. 7(a) shows the silicon substrate section after the addition of a first additive following the formation of the second mask (FIG. 6(d)). FIG. 7(b) shows the silicon substrate section after the addition of a second additive following the formation of a third mask. FIG. 7(c) shows the silicon substrate section after subjecting the substrate, for which the above processes have been completed, to a heat treatment to make the third mask disappear automatically and furthermore densify the porous silicon regions.

The thin film forming step S1 and the thin film partial removal step S2 in the fifth embodiment are respectively substantially the same as the same steps in the third embodiment (FIG. 6(a)). The porous region forming step S3 in the fifth embodiment is substantially the same as the same step in the third embodiment (FIG. 6(b)). The remaining thin film portion removal step S4 in the fifth embodiment is substantially the same as the same step in the third embodiment (FIG. 6(c)). However, in the fifth embodiment, porous silicon regions 21A and 22A and porous silicon regions 21B and 22B are formed. More specifically, two openings 12 are formed in the carbon thin film 11, the porous silicon regions 21A and 22A are formed below one of the openings 12, and the porous silicon regions 21B and 22B are formed below the other opening 12.

In the fifth embodiment, after the remaining thin film portion (first mask) is removed in the remaining thin film portion removal step S4 (FIG. 6(c)), the second mask is formed (FIG. 6(d)), a first additive is doped into the one porous silicon region 21A (FIG. 7(a)), and furthermore the third mask is formed, a second additive is doped into the other porous silicon region 21B, and thereafter, the porous silicon regions are densified (FIG. 7(c)). In particular, the following are carried out.

As shown in FIG. 6(d), in a second mask forming step after the remaining thin film portion removal step S4, a new second carbon film (second thin film) is formed, in the same manner as in the thin film forming step S1, on the silicon substrate 10, from which the remaining thin film portion (first mask) has been removed (second thin film forming step). Then, in the same manner as in the thin film partial removal step S2, a new opening 15 is formed in the carbon film by the photoetching method and the above-described oxygen plasma treatment as shown in FIG. 6(d), and the second mask 13 is thereby formed (second thin film partial removal step). The opening 15 is positioned above the one porous silicon region 21A.

In a first adding step after the second mask forming step, a titanium organometallic substance is doped as a first additive by subjecting the substrate 10, to which the above-described treatment has been performed, to the same process as that of the second embodiment, and the porous silicon region 21A, positioned below the opening 15, is converted into a titanium-doped porous silicon region 31 (FIG. 7(a)). Thereafter, in the same manner as in the remaining thin film portion removal step S4, the second mask layer 13 is oxidized and removed by oxygen plasma (second remaining thin film portion removal step).

In a third mask forming step after first adding step, first, a new third carbon film (third thin film) is formed in the same manner as in the thin film forming step S1 (third thin film forming step). Then, in the same manner as in the thin film partial removal step S2, a new opening 16 is formed in the carbon film by the photoetching method and the above-described oxygen plasma treatment, and the third mask 14 is thereby formed (third thin film partial removal step). The opening 16 is positioned above the other porous silicon region 21B. In a subsequent second adding step, an organometallic compound of erbium (Er), which is a rare earth metal, is selectively doped into the porous silicon region 21B positioned below the opening 16 to thereby convert this region 21B into a porous silicon region 32 that is doped with erbium as a second additive (FIG. 7(b)).

In a densification step after the second addition step, the silicon substrate 10 is subject to heat treatment at 850° C. in a dry oxygen flow in the same manner as in the fourth embodiment. By this treatment, the respective porous silicon regions are converted to porous silica. Also, the mask layer 14 of the third carbon film disappears due to oxidation (third remaining film portion removal step). The substrate 10 is furthermore treated in a wet oxygen flow of 1200° C. to densify the respective porous silica. By the above processes, a dense silica region 41, doped with titanium, and a dense silica region 42, doped with erbium, can be integrated monolithically on the same silicon substrate (FIG. 7(c)).

Because the doped silica regions 41 and 42 are higher in refractive index than the non-doped silica regions 51 and 52, the doped silica regions 41 and 42 have properties of cores, and the non-doped silica regions 51 and 52 have properties of clads. The surfaces 60 of the regions 41 and 51 and the regions 42 and 52 at the side of the principal surface of the silicon substrate are surfaces at which the silica has fused and has become densified and are thus extremely smooth surfaces.

### First Comparative Example

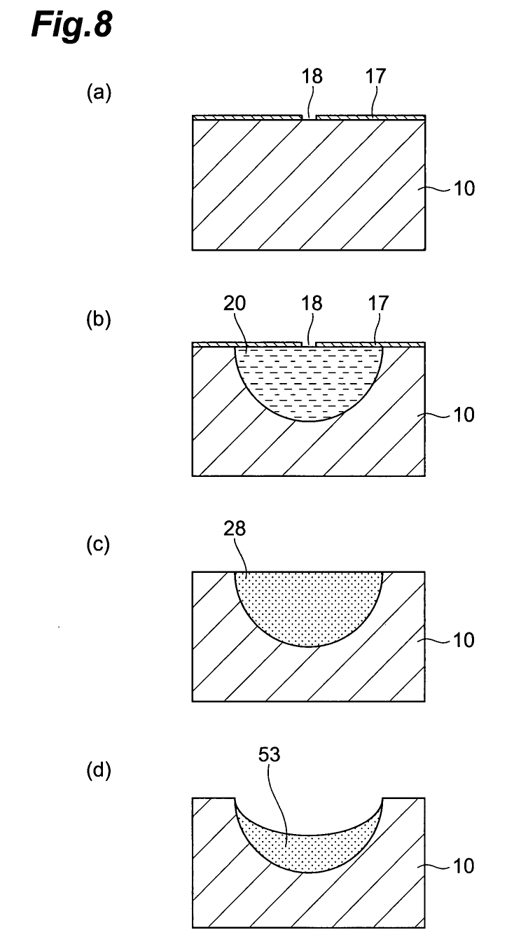

A first comparative example to be compared to the first embodiment shall now be described. FIG. 8 shows sectional view for describing step of a silicon substrate processing method according to the first comparative example. FIG. 8(a) shows a silicon substrate section after a thin film forming step and a thin film partial removal step. FIG. 8(b) shows the silicon substrate section after a porous region forming step. FIG. 8(c) shows the silicon substrate section after a remaining thin film portion removal step. FIG. 8(d) shows the silicon substrate section after a densification step.

In the thin film forming step in the first comparative example, a thin film 17, formed of silicon nitride (SiNₓ) of several 100 nm thickness, is formed on a highly-doped, p-type (100) silicon substrate 10 of 3-inch diameter by a plasma CVD method, using silane (SiH₄), ammonia (NH₃), and hydrogen (H₂) as the main raw materials.

In the thin film partial removal step in the first comparative example, a resist is coated to a thickness of approximately 1.5 μm onto the silicon substrate 10, on which the thin film 17 has been formed, a resist pattern is formed by exposure using a photomask, a desired opening 18 is formed in the thin film 17 by reactive ion etching (RIE), mainly using CF₄ and oxygen (O₂), and thereafter the resist is removed (FIG. 8(a)).

The porous region forming step in the first comparative example is the same as the same step in the first embodiment (FIG. 8(b)).

In the remaining thin film portion removal step in the first comparative example, the substrate 10, in which the porous silicon region 20 was formed by the above-described processes, is subject to an RIE method, using electrical discharge of a gas, mainly constituted of the CF₄ and oxygen (O₂) used in the patterning of the mask layer of this comparative example, to remove the silicon nitride mask layer 17 on the substrate 10 (FIG. 8(c)). This is done because the silicon nitride mask layer 17 cannot be removed effectively by the oxygen plasma indicated for the first embodiment.

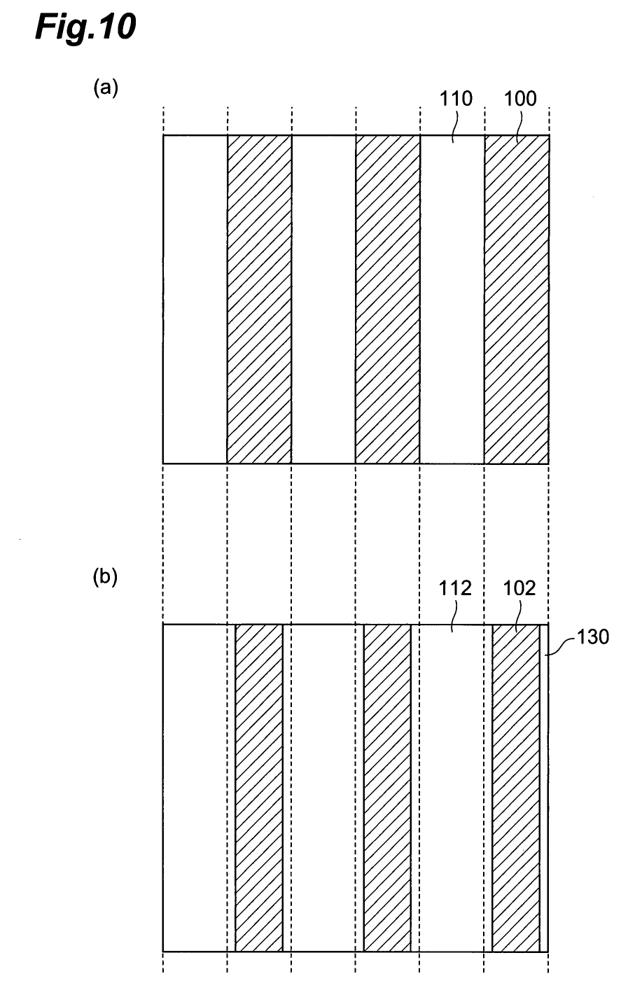

By the above-described method, the silicon nitride mask layer 17 can be removed as shown in FIG. 8(c). However, a fluorine-based plasma etches not only the silicon nitride layer but also etches the silicon crystal surface. The influence of this etching of silicon atoms is especially significant for the porous silicon 20, which has an extremely large specific surface area due to fine, nanosize pores being distributed across the entirety of the region. As indicated by the conceptual diagram of FIG. 10, fluorine-based active species that are excited by the plasma enter into the nanopores 110 of porous silicon and etch the surfaces of the fine silicon columns 100. If the surfaces of the fine silicon columns 100 are etched even slightly, the proportion of loss of silicon atoms will be great for the entire porous silicon region, which has an extremely large specific surface area.

Here, measurement of the total mass of the silicon substrate before and after the mask layer removal step showed that, in comparison to the state before removal (FIG. 8(b)), there is a clear mass loss in the order of several milligrams (mg) in the state after removal (FIG. 8(c)). This mass loss cannot be explained by just the mass loss due to etching of the silicon nitride, and it is considered that the mass loss of fine silicon column loss portions 130, etched by the fluorine-based active species in the interior of the porous silicon region, is added. It is interpreted that the porous silicon 20 (FIG. 8(b)), prepared with the porosity and pore diameter being controlled, is changed to a porous silicon 28 (FIG. 8(c)) of increased porosity (void portion) by the silicon nitride film mask layer removal step.

The silicon substrate, from which the mask layer has been removed as described above, is oxidized at 850° C. in a dry oxygen atmosphere and then densified at 1200° C. in a wet oxygen atmosphere in the same manner as in the fourth embodiment. As a result, the surface of the silica glass 53, to which the porous silicon 28 has changed, depresses greatly (FIG. 8(d)). This is due to the increase in the porosity of the porous silicon 28 in FIG. 8(c) and the decrease in the number of silicon atoms in the porous silicon region.

### Comparison of the First Embodiment, Etc., and the First Comparative Example

The first embodiment and the first comparative example shall now be compared. With the first comparative example, in which a silicon nitride film is used as a mask, in regard to the total mass of the silicon substrate before and after the mask layer removal step, a mass loss in the order of several milligrams (mg) is clearly seen after the mask removal. Also, by densification, the volume of the silica region 53 decreases in comparison to the volume of the porous silicon region 28. This is considered to be due to the mass loss at the surfaces of the fine silicon columns 100 in the interior of the porous silicon region due to the fluorine-based active species.

In contrast, with the first embodiment using a carbon film as a mask, in regard to total mass of the silicon substrate before and after the remaining thin film portion removal step S4, only an extremely slight mass change in the order of several tenths of a milligram, which is within the range of error, is seen. This is considered to be because the loss of mass due to the oxidation loss of the carbon film 11 is substantially cancelled out by the increase in mass due to the formation of the surface oxidized layer 120 by surface oxidation of the fine silicon columns 100 inside the porous silicon region 20 as shown in the conceptual diagram of FIG. 11(b).

As is thus clear from the comparison with the comparative example, with the silicon substrate processing method according to each embodiment, because a carbon thin film is used as a mask layer, an oxygen-based plasma can be used for patterning of the mask layer and patterning of extremely high selectivity, with which the etching of the silicon substrate is practically zero, can be achieved. Because the carbon thin film mask layer can be removed by the oxygen-based plasma, by oxidizing the surface layers of the fine silicon columns in the selectively formed porous silicon region, the mask layer can be removed from the surface of the porous silicon region in a state in which the decrease in the number of silicon atoms inside the porous silicon region is prevented and the porosity and the pore diameter are practically maintained.

Furthermore, because of the above, mask processes can be performed a plurality of times as was described with the fifth embodiment. Different regions of porous silicon that have been prepared in a single step can thus be doped with different types of impurities (additives). It thus becomes possible to prepare an optical integration circuit, having a passive optical waveguide and an active optical amplification waveguide, doped, for example with Er, which is a kind of a rare earth element, integrated monolithically on the same silicon substrate.

### Second Comparative Example

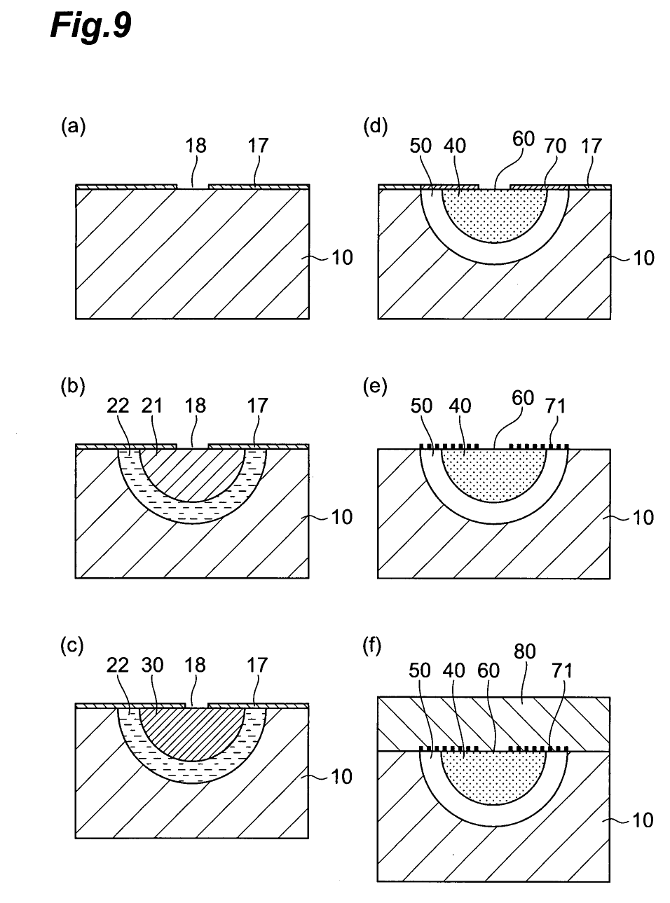

A second comparative example to be compared with the fourth embodiment shall now be described. FIG. 9 shows sectional view for describing step of the silicon substrate processing method according to the second comparative example. FIG. 9(a) shows a silicon substrate section after a thin film forming step and a thin film partial removal step. FIG. 9(b) shows the silicon substrate section after a porous region forming step. FIG. 9(c) shows the silicon substrate section, with which an additive is doped into the porous silicon region after the porous region forming step. FIG. 9(d) shows the silicon substrate section after oxidation and densification. FIG. 9(e) shows the silicon substrate section after a remaining thin film portion removal step. FIG. 9(f) shows the silicon substrate section, with which an upper clad is formed after the remaining thin film portion removal step.

The thin film forming step and the thin film partial removal step in the second comparative example are respectively the same as the same steps in the first comparative example, and by these steps, the thin film 17, formed of silicon nitride (SiNₓ), is deposited (FIG. 9(a)). The porous region forming step in the second comparative example is the same as the same step in the fourth embodiment (FIG. 9(b)). The impurity adding step in the second comparative example is the same as the same step in the fourth embodiment (FIG. 9(c)).

In the oxidation and densification step in the second comparative example, the silicon substrate 10 is oxidized at 850° C. in a dry oxygen gas atmosphere and then densified at 1200° C. in a wet oxygen atmosphere in the same manner as in the fourth embodiment. A doped silica core region 40 and a non-doped silica clad region 50 are thereby formed (FIG. 9(d)).

However, the silicon nitride mask layer 17 is not completely oxidized in the above-mentioned oxidation step and it is clearly seen that the form thereof remains. In particular, a surface shape, having an unevenness that, although being irregular, has periodicity, is exhibited at a portion 70 in contact with the densified silica regions 40 and 50. Meanwhile, a surface 60, corresponding to a mask layer opening 18 is a smooth surface of fused silica.

In the remaining thin film portion removal step in the second comparative example, an etching treatment by a fluorine-based plasma is performed to remove the mask layer 17 remaining on the surface of the silicon substrate 10 that has been subject to the above-described processes (FIG. 9(e)). At the portion at which the periodically uneven portion 70 was seen in FIG. 9(d), a similar, periodically uneven portion 71 is seen even after the etching treatment. The above-described periodically uneven structure, formed at the interface of the mask layer and the silica region in the heat treatment step of densifying the silica, is imprinted near the surfaces of the silica regions 40 and 50 as well and cannot be removed just by etching of the surface.

An upper clad 80 is formed on the principal surface of the silicon substrate 10 after the remaining thin film portion removal step (FIG. 9(f)). This upper clad 80 is formed, for example, of silica. By the above-described processes, if the regions 40 and 50 are long in one direction (the direction perpendicular to the paper surface), a optical waveguide, having the region 50 and the upper clad 80 as clads and the region 40 as a core, is prepared.

Although the period of the above-described periodically uneven structure is irregular it is in the submicron order to the order of several microns. When such an irregular, periodic structure is present, especially at the core surface of an optical waveguide, it clearly causes light scattering loss.

In this second comparative example, because the remaining thin film portion is removed after oxidation and densification of the porous silicon, the change of the total mass of the silicon substrate before and after the mask layer removal step corresponds to just the mass of the silicon nitride mask layer.

### Comparison of the Fourth Embodiment and the Second Comparative Example

The fourth embodiment and the second comparative example shall now be compared. In the second comparative example, during heat treatment at 1200° C., the silica exhibits fluidity, fuses, and contacts the remaining silicon nitride mask layer 17. It is considered that because the fused silica contacts the solid mask layer 17 that differs in surface properties, the periodically uneven shape is formed on the silica surface. Meanwhile, the surface portion corresponding to the opening 18 of the mask 17 is a free surface in the fused state and thus becomes flat.

Meanwhile, with the fourth embodiment, because by the heat treatment at 1200° C., the silica is put in a fused state that exhibits viscous fluidity, densification of the silica occurs. Because in this process, the surfaces 60 of the regions 40 and 50 at the side of the principal surface of the substrate are in states of free surfaces that are not in contact with any solid substance, the history of fusion and flow as free surfaces is preserved and the surfaces 60 are thus made extremely smooth.

### Third Comparative Example

A third comparative example to be compared with the first embodiment shall now be described. With this comparative example, a treatment of removing organic contaminants on the surface is performed as a surface treatment of the silicon substrate to be subject to the thin film forming step S1. A carbon thin film layer 11 is formed on this silicon substrate surface under the same conditions as those used in the first embodiment. After then carrying out the remaining thin film portion removal step S2, the silicon substrate 10 is immersed in a hydrofluoric acid solution to carry out the porous region forming step S4.

By just being immersed in the hydrofluoric acid solution, the carbon thin film layer 11 undergoes a phenomenon of peeling from the opening 12 of the mask and pinholes in the carbon thin film layer as starting points and, in some cases, does not serve the function of an anodizing mask for the silicon. This is interpreted to be due to the extremely thin silicon oxide film layer of the silicon substrate surface, which is the base of the carbon thin film layer, being etched by the hydrofluoric acid and the carbon thin film layer thereby becoming lifted off and peeled.

In contrast, by subjecting the silicon substrate surface to the hydrogen termination treatment before the forming of the carbon thin film 11, a carbon thin film of good, close adhesion that can withstand the porous region forming step by anodization in the hydrofluoric acid solution, as described above with the respective embodiments, can be formed. The above-mentioned hydrogen termination treatment of the silicon substrate surface is unnecessary for the forming of the carbon thin films used as the second mask layer 13, the third mask layer 14, etc., in the fifth embodiment.

As is clear from the comparison with the comparative examples, with the silicon substrate processing method of each embodiment, because the porous silicon is oxidized at the same time as removing the remaining thin film portion and is furthermore densified, the surfaces 60 of the silica 40 and 50 at the one principal surface side of the substrate are made smooth, and this is favorable in terms of preparing an optical waveguide, etc.

Although in the fifth embodiment, after adding titanium (first additive) to the porous silicon region 21A, erbium (second additive) is added to the porous silicon region 21B upon forming the third mask layer 14, an oxidation treatment may be carried out without forming the third mask layer 14. The steps subsequent the second mask forming step (FIG. 6(d)) in this case shall now be described.

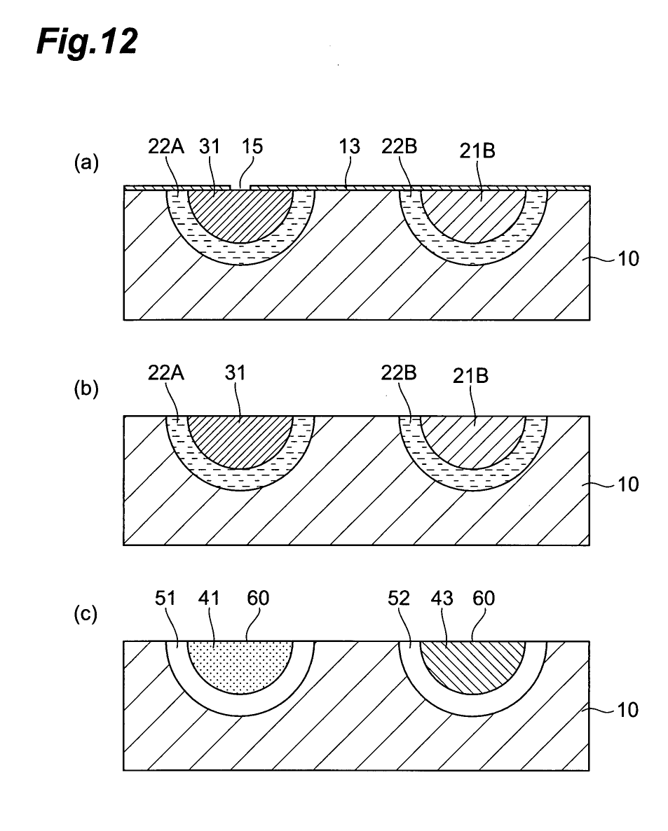

As shown in FIG. 12(a), in the first adding step after the second mask forming step, the porous silicon region (first region) 21A, positioned below the opening 15, is converted to the titanium-doped porous silicon region 31 by the same process as that of the fifth embodiment. Then, in the same manner as in the remaining thin film portion removal step S4, the second mask layer 13 is removed. The silicon substrate 10, having the porous silicon region 31, to which the first additive has been added, and the porous silicon region 21B, to which an additive has not been added, can thus be obtained as shown in FIG. 12(b).

Also, by heating further after oxidation and thereby respectively densifying the porous silicon regions 31 and 21B, the dense silica region 41, doped with titanium, and the dense silica region 43, to which an impurity is not added, may be integrated on the same silicon substrate 10 as shown in FIG. 12(c).

When the second thin film is thus used as a mask layer, an additive can be added more reliably to the desired regions among the porous silicon regions 21A, 21B, 22A, and 22B.

Yet furthermore, an embodiment such as the following is also possible. A sixth embodiment of the silicon substrate processing method according to this invention shall now be described.

### Sixth Embodiment

With a sixth embodiment, in between the porous region forming step S3 and the remaining thin film portion removal step S4, a step of further forming a carbon film on the mask layer 13, a step of forming an opening in this carbon film, and a step of doping the porous silicon region with an additive as an impurity are furthermore provided.

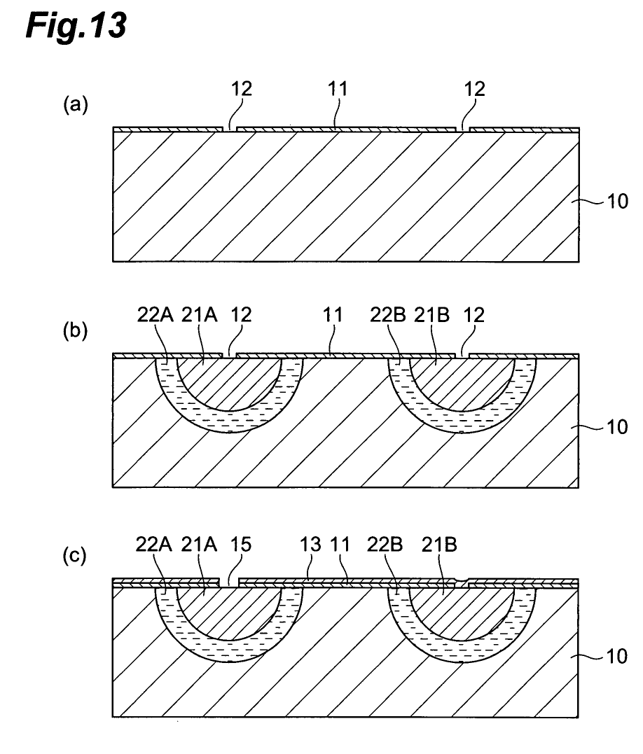

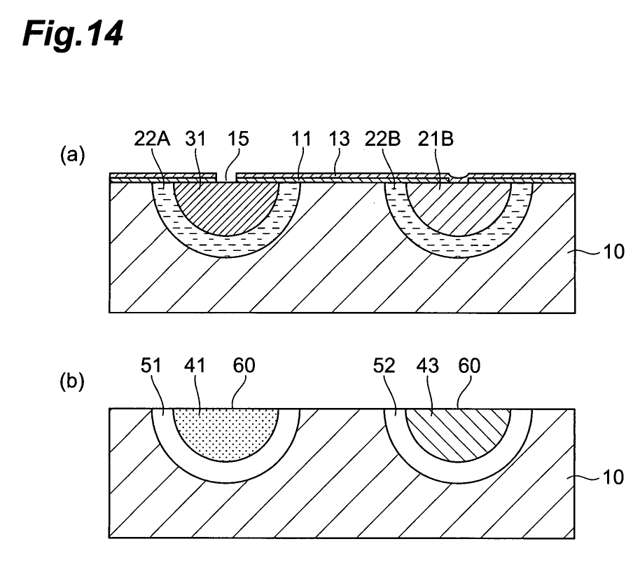

FIG. 13 and FIG. 14 show sectional views for describing steps of a silicon substrate processing method according to a sixth embodiment of this invention. FIG. 13(a) shows a silicon substrate section after the thin film forming step S1 and the thin film partial removal step S2. FIG. 13(b) shows the silicon substrate section after the porous region forming step S3. FIG. 13(c) shows the silicon substrate section after a second mask is formed following the step of FIG. 13(b). FIG. 14(a) shows the silicon substrate section after the addition of an additive following the formation of the second mask (FIG. 13(c)). FIG. 14(b) shows the silicon substrate section after densification of the porous silicon regions.

The thin film forming step S1 and the thin film partial removal step S2 in the sixth embodiment are respectively substantially the same as the same steps in the fifth embodiment (FIG. 13(a)). The porous region forming step S3 in the sixth embodiment is substantially the same as the same step in the fifth embodiment (FIG. 13(b)). The remaining thin film portion removal step S4 in the sixth embodiment is substantially the same as the same step in the fifth embodiment (FIG. 14(b)). However, in the sixth embodiment, the first mask and the second mask are removed together in the remaining thin film portion removal step S4.

In the sixth embodiment, after the porous region forming step S3, the second mask 13 is furthermore formed (FIG. 13(c)) and an additive is doped into the one porous silicon region 21A (FIG. 14(a)). After then removing the first mask 11 and the second mask 13 together, the porous silicon regions are densified (FIG. 14(b)). Specifically, the following are carried out.

In the second mask forming step after the porous region forming step S3, a new second carbon film (second thin film) is formed in the same manner as in the thin film forming step S1 on the remaining thin film portion (first mask) as shown in FIG. 13(c) (second thin film forming step). Then, in the same manner as in the thin film partial removal step S2, a new opening 15 is formed in the carbon film (second thin film) and the first mask 11 by the photoetching method and the above-described oxygen plasma treatment as shown in FIG. 13(c), and the second mask 13 is thereby formed (second thin film partial removal step). The opening 15 is positioned above the one porous silicon region 21A.

In the adding step after the second mask forming step, a titanium organometallic substance is doped as the additive via the opening 15 by subjecting the substrate 10, on which the above-described treatment has been performed, to the same process as that of the fifth embodiment, and the porous silicon region 21A is thereby converted into the titanium-doped porous silicon region 31 (FIG. 14(a)). Thereafter, in the same manner as in the fifth embodiment, the silicon substrate 10 is heat treated at 850° C. in a dry oxygen flow. By this treatment, the respective porous silicon regions are converted to porous silica. Also, the mask layers 11 and 13, which are thin films on the principal surface having carbon as the main component, are made to disappear by oxidation (remaining thin film portion removal step S4). The substrate 10 is furthermore heat treated in a wet oxygen flow of 1200° C. to densify the respective porous silica.

By the above processes, the dense silica region 41, doped with titanium, and the dense silica region 43, which is not doped with an additive as an impurity, can be integrated monolithically on the same silicon substrate (FIG. 14(b)).

In this case, the surfaces 60 of the regions 41 and 51 and the regions 43 and 52 at the side of the principal surface of the silicon substrate are surfaces at which the silica has fused and densified and are thus extremely smooth surfaces. Also, because the mask layer 13 is layered onto the mask layer 11 and the mask layers 11 and 13 are removed together in the remaining thin film portion removal step S4, the time required for processing the silicon substrate 10 tends to be shortened in comparison to the case of removing the mask layers 11 and 13 separately.

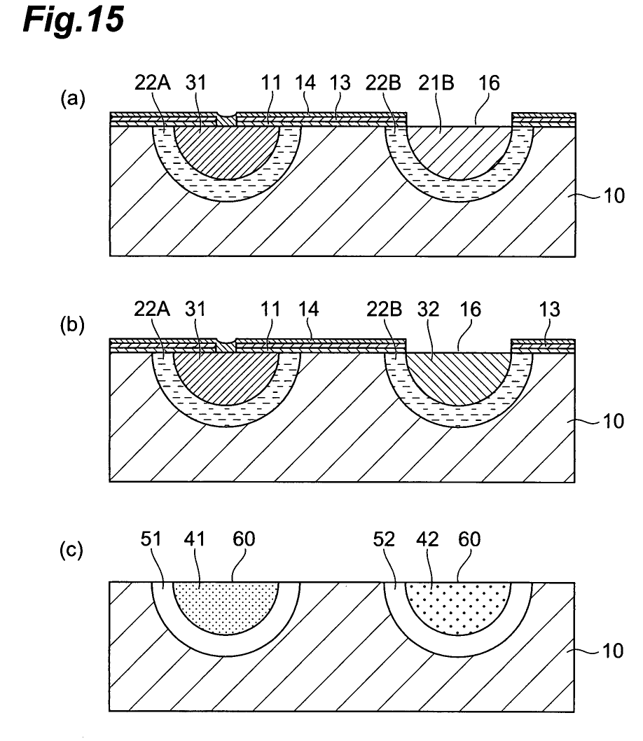

Although in the description of the sixth embodiment, the second mask layer 13 is formed on the first mask layer 11 to form the titanium-doped silica region 41, this invention is not restricted thereto. For example, by forming yet another new mask layer on the second mask layer 13, another additive can be doped favorably in the porous silicon region 21B in the same manner as in the fifth embodiment. FIG. 15 shows sectional view for describing step subsequent FIG. 14(a) in the case of adding an additive to the porous silicon region 21B.

In the case of adding an additive to the porous silicon region 21B, after the adding step of doping the porous silicon region 21A with titanium (FIG. 14(b)), yet another new third carbon film (third thin film) is formed on the second mask 13 in the same manner as in the thin film forming step S1 and as shown in FIG. 15(a) (third thin film forming step). Then, in the same manner as in the thin film partial removal step S2, an opening 16 is newly formed in the second mask 13 and the first mask 11 by the photoetching method and the above-described oxygen plasma treatment in the carbon film (third thin film), the second mask 13, and the third mask 14 is thereby be formed (third thin film partial removal step). The opening 16 is positioned above the other porous silicon region 21B.

An organometallic compound of erbium (Er), which is a rare earth metal, is then selectively doped into the porous silicon region 21B, positioned below the opening 16 as shown in FIG. 15(b) (second adding step), and the region 21B is thereby converted to the porous silicon region 32 that is doped with erbium as the second additive.

Thereafter, in the same manner as the removal of the mask layers in the above-described sixth embodiment, the mask layers 11, 13, and 14, which are thin films on the principal surface that have carbon as the main component, are removed together and furthermore, the respective porous silica regions are densified in the thin film partial removal step S4 as shown in FIG. 15(c). By the above processes, the dense silica region 41, doped with titanium, and the dense silica region 42, doped with erbium, can be integrated monolithically on the same silicon substrate (FIG. 15(c)).

1: A silicon substrate processing method comprising:
a thin film forming step of forming a thin film, having carbon as a main component, on at least one principal surface of a silicon substrate;
a thin film partial removal step of removing, from among the thin film formed in the thin film forming step, a thin film portion at a partial region of the one principal surface;
a porous region forming step of selectively forming a porous silicon region at a surrounding region including the partial region, by subjecting the silicon substrate, which has been subject to the thin film partial removal step, to anodization in an electrolytic solution containing hydrofluoric acid; and
a remaining thin film portion removal step of removing the remaining portion of the thin film on the one principal surface of the silicon substrate, which has been subject to the porous region forming step, in an oxidizing atmosphere and at the same time oxidizing at least a portion of the porous silicon region.

2: The silicon substrate processing method according to claim 1, wherein the thin film, formed in the thin film forming step, is a hard carbon film.

3: The silicon substrate processing method according to claim 1, wherein in the thin film forming step, the thin film having carbon as the main component is formed after applying a hydrogen termination treatment to a surface of at least one principal surface of the silicon substrate.

4: The silicon substrate processing method according to claim 1, wherein in the remaining thin film portion removal step, the remaining portion of the thin film is removed in an oxidizing atmosphere and at the same time, the entirety of the porous silicon region is oxidized.

5: The silicon substrate processing method according to claim 1, wherein the oxidizing atmosphere in the remaining thin film portion removal step is an oxygen-containing atmosphere of no less than 500° C.

6: The silicon substrate processing method according to claim 1, wherein the oxidizing atmosphere in the remaining thin film portion removal step is a plasma atmosphere having oxygen as a main component.

7: The silicon substrate processing method according to claim 1, wherein the oxidizing atmosphere in the remaining thin film portion removal step is an ozone atmosphere.

8: The silicon substrate processing method according to claim 1, wherein the oxidizing atmosphere in the remaining thin film portion removal step is a strongly oxidizing liquid atmosphere.

9: The silicon substrate processing method according to claim 1, further comprising: an adding step of adding an additive to the porous silicon region formed by the porous region forming step; and
wherein in the remaining thin film portion removal step, the remaining portion of the thin film on the one principal surface of the silicon substrate, which has been subject to the adding step, is removed in an oxidizing atmosphere and at the same time, at least a portion of the porous silicon region is oxidized.

10: The silicon substrate processing method according to claim 1, further comprising: an adding step of adding an additive to the porous silicon region belonging to the silicon substrate, which has been subject to the remaining thin film portion removal step.

11: The silicon substrate processing method according to claim 1, further comprising:
a second thin film forming step of forming a second thin film, having carbon as a main component, on the one principal surface of the silicon substrate, which has been subject to the porous region forming step;
a second thin film partial removal step of removing a portion of a portion of the second thin film positioned above the porous silicon region;
an adding step of adding an additive to the porous silicon region via the portion of the second thin film that has been removed by the second thin film partial removal step; and
a second remaining thin film portion removal step of removing the remaining portion of the second thin film on the one principal surface, which has been subject to the adding step, in an oxidizing atmosphere and at the same time oxidizing at least a portion of the porous silicon region.

12: The silicon substrate processing method according to claim 1, further comprising:
a second thin film forming step of forming a second thin film, having carbon as a main component, on the one principal surface of the silicon substrate, which has been subject to the porous region forming step;
a second thin film partial removal step of removing a portion of a portion of the second thin film positioned above the porous silicon region; and
an adding step of adding an additive to the porous silicon region via the portion of the second thin film that has been removed by the second thin film partial removal step; and
wherein in the remaining thin film portion removal step, the remaining portion of thin films, having carbon as a main component, on the one principal surface, which has been subject to the adding step, is removed in an oxidizing atmosphere and at the same time, at least a portion of the porous silicon region is oxidized.
